(19) United States
(12) Patent Application Publication
(10) Pub. No.: US 2009/0317943 A1
(43) Pub. Date: Dec. 24, 2009

(54) Alignment of Semiconducting Nanowires on Metal Electrodes

(76) Inventors: Kyung Soo Park, Seoul (KR); Seok Joon Kwon, seoul (KR); Jae Gwan Park, seoul (KR); Jae-Hwan Park, Seoul (KR); Young Jin Choi, Seoul (KR); Hae Young Kang, Seoul (KR)

Correspondence Address: FROMMER LAWRENCE & HAUG, 745 FIFTH AVENUE- 10TH FL., NEW YORK, NY, 10151, US

(21) Appl. No.: 12/374,750

(22) PCT Filed: Nov. 28, 2006
(86) PCT No.: PCT/KR06/05054

§ 371 Date: May 7, 2009

(30) Foreign Application Priority Data
Jul. 27, 2006 (KR) 10-2006-0070528

(51) Int. Cl. H01L 21/283

(52) U.S. Cl. 438/104; 257/E21.159

(57) ABSTRACT

The present invention relates to a method for aligning semiconducting nanowires on a metal electrode (12), more particularly to a method for aligning semiconducting nanowires on a metal electrode (12) by which a zinc oxide nanowire and a silicon nanowire are synthesized on a specific region of an electrode made of Al, Ti, Pt, etc. and the nanowires are aligned on the wafer scale instantly as they are synthesized. The method for aligning semiconducting nanowires on a metal electrode (12) in accordance with the present invention makes it possible to manufacture multiple nanowire devices at low cost. Thus, the method in accordance with the present invention can be effectively utilized to produce various nano devices, including electronic devices, optoelectronic devices, laser devices, chemical sensors, etc. in large quantity.

### TECHNICAL FIELD

The present invention relates to a method for aligning semiconducting nanowires on a metal electrode, more particularly to a method for aligning semiconducting nanowires on a metal electrode by which a zinc oxide nanowire and a silicon nanowire are synthesized on a specific region of an electrode made of Al, Ti, Pt, etc. and the nanowires are aligned on the wafer scale instantly as they are synthesized.

### BACKGROUND ART

With the recent advance in semiconductor techniques, electronic devices are becoming more and more integrated.

Especially, in the field of ultra large-scale integrated circuits including CMOS, etc., the line width of the devices is becoming smaller with the high-level integration.

As the size of devices becomes small, the importance of the nanowires that electrically connect them has been increasingly emphasized.

The nanowires find a multitude of applications in the field of optics, mechanics, electronics, etc.

In general, the nanowires are made of GaAs, GaN, InP, ZnO, etc. and researches are actively carried out on their use such as a light-emitting device.

Particularly, GaN, GaAs, ZnO, etc. are used to develop blue light-emitting devices. And, InAs and InP are utilized in the region of 1.3 to 1.5 mm.

Because of the advantageous features attained within nano size range and superior crystallinity, the nanowires can be utilized in a variety of electronic devices, opto-electronic devices, sensors, etc.

The semiconducting nanowire that has been researched most is zinc oxide (ZnO) nanowire. One-dimensional nanoscale objects with a variety of forms (nanowire, nanorod, nanosheet, etc.) have been synthesized by carbothermal reduction method, chemical vapor deposition (CVD), wet chemical method, pulsed laser deposition (PLD), etc. and their applicability for use as optoelectronic devices, laser devices, chemical sensors, etc. have been identified.

Silicon nanowire can be used in various electronic devices. Typically, silicon nanowire is synthesized by chemical vapor deposition using a gold catalyst and a certain precursor vapor phase source (e.g., silane gas).

However, with the utilization of nanowire devices in the semiconductor field, as compared with the conventional thin film-based technology, the alignment of the nanowires has been raised as a major obstacle.

In the conventional method, after each nanowire is synthesized, an independent process such as electron beam lithography must be performed. Then, electrodes are adhered thereto to obtain an operable device.

This process, undesirably, is complicated and expensive and thus not suitable for mass production at low cost.

Accordingly, an object of the present invention is to solve this problem and provide a method for aligning semiconducting nanowires on a metal electrode by which a zinc oxide nanowire and a silicon nanowire are synthesized on a specifically defined region of an electrode made of aluminum, titanium, platinum, etc. and the nanowires are aligned on the wafer scale instantly as they are synthesized. In accordance with the present invention, it is possible to manufacture multiple nanowire devices at once at low cost. Thus, the method in accordance with the present invention can be effectively utilized to produce various nano devices, including electronic devices, optoelectronic devices, laser devices, chemical sensors, etc., in large quantity.

### DISCLOSURE

Hereunder is given a detailed description of the present invention.

The method for aligning semiconducting nanowires on a metal electrode in accordance with the present invention comprises:

a first step of patterning a gold catalyst layer on a conducting electrode made of aluminum (Al), titanium (Ti) and platinum (Pt); and

a second step of synthesizing a zinc oxide nanowire and a silicon nanowire in the region where the gold catalyst layer is patterned, as the nanowires are aligned at the same time.

### DESCRIPTION OF DRAWINGS

FIG. 1 illustrates the devices regularly aligned on a wafer and the nanowires that have grown with patterns as aligned on a conducting electrode in accordance with the present invention.

FIG. 2 illustrates the process of patterning a conducting electrode and a gold catalyst layer using a mask in accordance with the present invention.

FIG. 3 shows the metals that help the growth of the zinc oxide (ZnO) nanowire and the silicon (Si) nanowire depending on the composition of the reaction gas and the reaction temperature in accordance with the present invention.

FIG. 4 shows that the zinc oxide (ZnO) nanowire grows only on the gold catalyst, not on a conductive electrode made of aluminum in accordance with the present invention.

FIG. 5 shows that the silicon (Si) nanowire grows only on the gold catalyst, not on a conductive electrode made of titanium in accordance with the present invention.

FIG. 6 shows that the zinc oxide nanowire grows both on a conductive electrode made of platinum in accordance with the present invention and the gold catalyst.

### BEST MODE

Now, the present invention is described in more detail referring to the accompanying drawings.

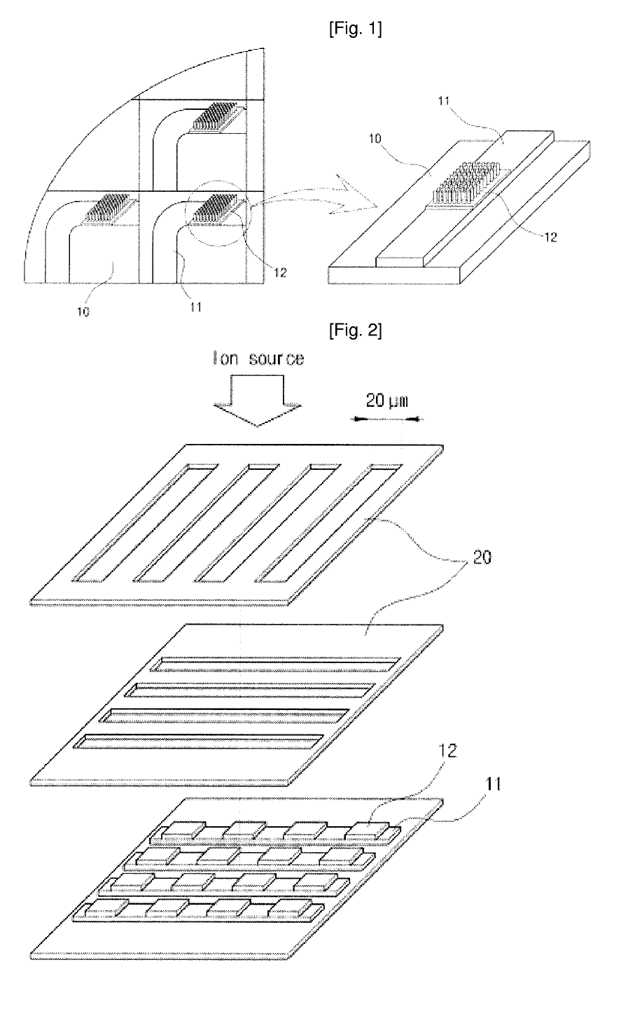

FIG. 1 illustrates the devices regularly aligned on a wafer and the nanowires that have grown with patterns as aligned on a conducting electrode in accordance with the present invention.

FIG. 2 illustrates the process of patterning a conducting electrode and a gold catalyst layer using a mask in accordance with the present invention.

In a preferred embodiment of the present invention, a conducting electrode (11) made of aluminum (Al), titanium (Ti), platinum (Pt), etc. is used on a semiconductor wafer (10), as illustrated in FIG. 1.

A gold catalyst layer (12) is patterned on the conducting electrode (11). First, the conducting electrode (11) is processed to a thickness of 3000-8000 Å and a line width of 100 μm by RF sputtering using a shadow mask (20), as illustrated in FIG. 2.

Typically, the patterning by the RF sputtering is performed under the condition of 30-80 W, argon (Ar) atmosphere and 10-20 mTorr.

A gold catalyst layer (12) is formed on the resultant conducting electrode (11). The gold catalyst layer (12) is selectively patterned so that nanowires may grow only on the specific region of the conducting electrode (Al, Ti, Pt) (11).

It is well known by those skilled in the art that, when gold is used in the catalyst layer (12), nanowires may grow as aligned on the desired site of the zinc oxide (ZnO) and silicon (Si) substrate.

It is because the source material reacts with the gold catalyst to form a eutectic alloy by the vapor-liquid-solid (VLS) mechanism.

In the present invention, the gold catalyst layer (12) is patterned to a thickness of 20-100 Å by ion sputtering.

Nanowires are synthesized after the gold catalyst layer (12) has been patterned on the conducting electrode (11) to a desired thickness by ion sputtering. A zinc oxide nanowire is synthesized by the carbothermal reduction method.

Zinc oxide and graphite powder (99.9%; ˜325 mesh; 1:1 mixture) are used as a source material. The reaction is performed at 800-1000° C. for 1-120 minutes.

If the reaction temperature is below 800° C., the eutectic alloy of the source material and the gold catalyst is not formed easily. In contrast, if the reaction temperature is above 1000° C., a 3D, rather than 1D, nanowire in the form of a large plate is obtained. If the reaction time is outside the above range, a 1D nanowire is not synthesized well or a 3D, rather than 1D, nanowire in the form of a large plate is obtained.

Argon (10-200 sccm) is used as a carrier gas and oxygen (0.1-10 sccm) is injected as a reaction gas.

If the flow rate of the argon gas is smaller than 10 sccm, the source material is not fully vaporized, thus causing difficulty in nanowire synthesis. Also, a flow rate larger than 200 sccm makes the nanowire synthesis difficult. If the flow rate of the reaction gas oxygen is outside the above range, a 1D nanowire is not synthesized well or a 3D, rather than 1D, nanowire in the form of a large plate is obtained.

Further, a silicon nanowire is synthesized by the chemical vapor deposition using a silane gas.

At a pressure of 1-100 Torr, a silane (SiH₄) gas and a hydrogen (H₂) gas diluted to 5% are injected to a metal-organic gas helium (He) at a flow rate of about 10-100 sccm and 10-200 sccm, respectively.

If the reaction pressure is outside the above range, the silicon nanowire is not synthesized properly. If the flow rate of the silane gas and the hydrogen gas is outside the above range, it is difficult to obtain a 1D nanowire or an amorphous SiO₂ nanowire is obtained.

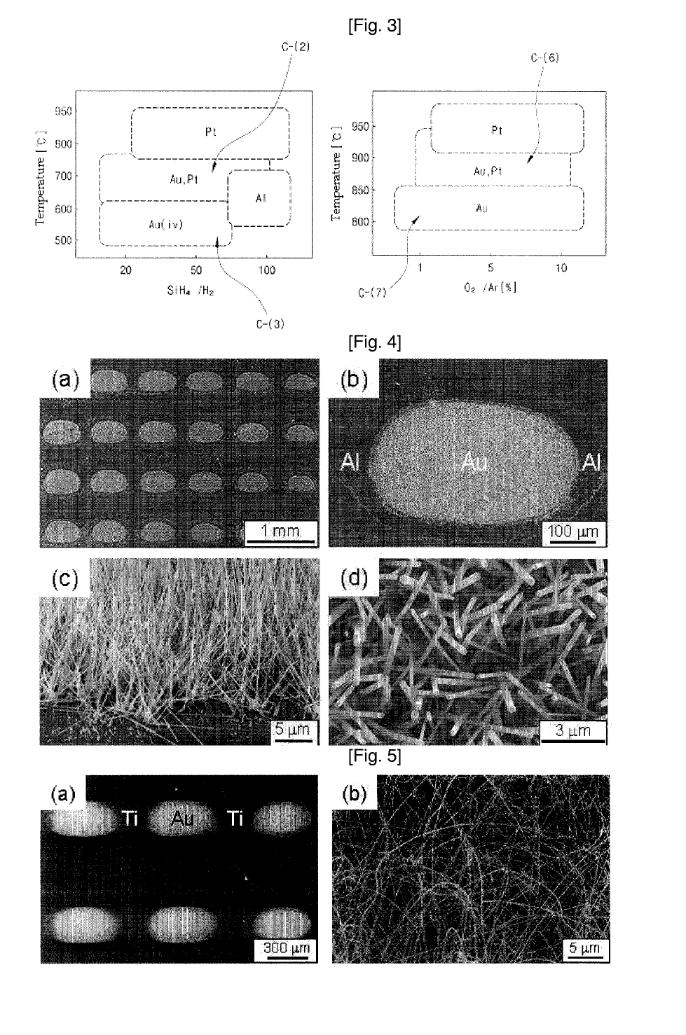

The metals that can give rise to zinc oxide and silicon nanowires under specific composition and reaction temperature are illustrated in FIG. 3.

That is, FIG. 3 shows the metals that help the growth of the zinc oxide (ZnO) nanowire and the silicon (Si) nanowire depending on the composition of the reaction gas and the reaction temperature.

For example, if the ratio of silane (SiH₄)/hydrogen (H₂) of the reaction gas is 10-80 and the reaction temperature is 500-600° C., the silicon nanowire grows only on gold (Au). If the ratio of silane (SiH₄)/hydrogen (H₂) of the reaction gas is 70-120 and the reaction temperature is 550-700° C., the silicon nanowire grows only on aluminum (Al). If the ratio of silane (SiH₄)/hydrogen (H₂) of the reaction gas is 10-100 and the reaction temperature is 600-750° C., the silicon nanowire grows on gold (Au) and platinum (Pt). If the ratio of silane (SiH₄)/hydrogen (H₂) of the reaction gas is 20-120 and the reaction temperature is 750-950° C., the silicon nanowire grows on platinum (Pt).

Also, if the ratio of oxygen/argon of the reaction gas is 0.5-12 and the reaction temperature is about 800-850° C., the zinc oxide nanowire grows only on gold (Au). If the ratio of oxygen/argon of the reaction gas is 1-10 and the reaction temperature is about 850-950° C., the zinc oxide nanowire grows on platinum (Pt) and gold (Au). And, if the ratio of oxygen/argon of the reaction gas is 2-12 and the reaction temperature is about 950-1000° C., the zinc oxide nanowire grows only on platinum (Pt).

The reason of elucidating the growth of the zinc oxide nanowire and the silicon nanowire on different metals depending on the composition and reaction gas is stated as follows: the eutectic temperature and the eutectic composition change when the source elements zinc (Zn) and silicon (Si) of the nanowires are mixed with the platinum (Pt), aluminum (Al) and titanium (Ti) metals of the conducting electrode (11), as shown in Table 1 below.

For example, because the eutectic temperature of zinc (Zn) and gold (Au) is 683° C., the zinc oxide nanowire can be synthesized on gold (Au) within a broad temperature range of 800-950° C. But, the nanowire is hardly synthesized on aluminum (Al) or titanium (Ti) as the Al₂O₃ and TiO₂ oxides are formed.

In case of the silicon nanowire, the inside of the reactor is under strong reduction atmosphere because the hydrogen (H₂) gas is injected, differently from the case of zinc oxide nanowire.

Therefore, the formation of Al₂O₃ or TiO₂ oxides is prevented and the silicon nanowire can be synthesized on aluminum (Al).

As for titanium (Ti), the synthesis of the silicon nanowire is very difficult because the eutectic temperature of silicon (Si) and titanium (Ti) is very high at no less than 1300° C.

TABLE 1

| | Melting point | Eutectic | Eutectic |
|---|---|---|---|
| Alloy | (° C.) | composition (wt %) | temperature (° C.) |
| Al—Zn | 660 | 11:89 | 381 |
| Ti—Zn | 1670 | 99:01 | 419 |
| Pt—Zn | 1769 | — | — |
| Au—Zn | 1064 | 85:15 | 683 |
| Al—Si | 660 | 88:12 | 577 |
| Ti—Si | 1670 | 92:08 | 1330 |
| Pt—Si | 1769 | 77:23 | 979 |
| Au—Si | 1064 | 97:03 | 363 |

FIG. 4 shows that the zinc oxide (ZnO) nanowire grows only on the gold catalyst, not on the aluminum conducting electrode (11). The zinc oxide nanowire shown in the figure was obtained by using an aluminum (Al, 5000 Å) conducting electrode (11), a part of which is patterned with a gold catalyst layer (12) (Au, 100 Å) under the synthesis condition C-(7) of FIG. 3.

As seen in the figure, the zinc oxide nanowire selectively grew only on the region where the gold catalyst layer (12) was patterned.

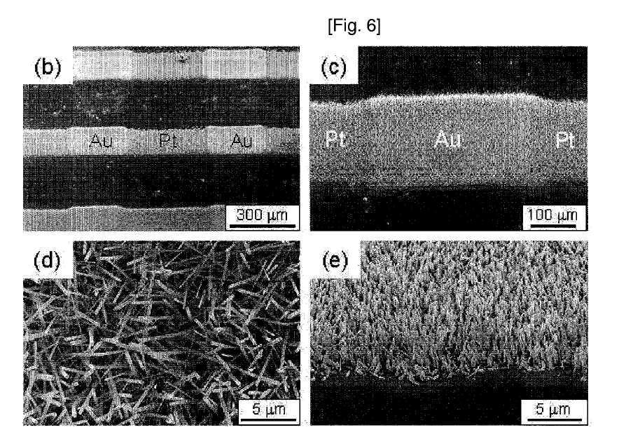

FIG. 5 shows that the silicon (Si) nanowire grows only on the gold catalyst, not on the titanium conducting electrode (11). The silicon nanowire shown in the figure was obtained by using a titanium (Ti, 5000 Å) conducting electrode (11), a part of which is patterned with a gold catalyst layer (12) (Au, 100 Å) under the synthesis condition C-(3) of FIG. 3.

As seen in the figure, the silicon nanowire selectively grew only on the region where the gold catalyst layer (12) was patterned.

FIG. 6 shows that the zinc oxide nanowire grows both on the platinum conducting electrode (11) and the gold catalyst. The zinc oxide nanowire shown in the figure was obtained by using a platinum (Pt, 5000 Å) conducting electrode (11), a part of which is patterned with a gold catalyst layer (12) (Au, 100 Å) under the synthesis condition C-(6) of FIG. 3.

As seen in the figure, the zinc oxide nanowire grew not only on the region where the gold catalyst layer (12) was patterned but also on the platinum electrode (11).

In accordance with the method for aligning semiconducting nanowires on a metal electrode of the present invention, a zinc oxide nanowire and a silicon nanowire are synthesized on a specific region of an electrode made of aluminum, titanium, platinum, etc. and the nanowires are aligned on the wafer scale instantly as they are synthesized. Accordingly, it is possible to manufacture multiple nanowire devices at once at low cost. Thus, the method in accordance with the present invention can be effectively utilized to produce various nano devices, including electronic devices, optoelectronic devices, laser devices, chemical sensors, etc., in large quantity.

### INDUSTRIAL APPLICABILITY

As apparent from the above description, the method for aligning semiconducting nanowires on a metal electrode in accordance with the present invention makes it possible to manufacture multiple nanowire devices at once at low cost. Thus, the method in accordance with the present invention can be effectively utilized to produce various nano devices, including electronic devices, optoelectronic devices, laser devices, chemical sensors, etc., in large quantity.

Those skilled in the art will appreciate that the concepts and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the present invention as set forth in the appended claims.

1. A method for aligning semiconducting nanowires on a metal electrode comprising:
a first step of patterning a gold catalyst layer on a conducting electrode made of aluminum (Al), titanium (Ti) and platinum (Pt); and
a second step of synthesizing a zinc oxide nanowire and a silicon nanowire in the region where the gold catalyst layer is patterned instantly as the nanowires are aligned.

2. The method for aligning semiconducting nanowires on a metal electrode as set forth in claim 1, wherein the conducting electrode has a thickness of 3000-8000 Å and a line width of 100 μm.

3. The method for aligning semiconducting nanowires on a metal electrode as set forth in claim 1, wherein the gold catalyst layer has a thickness of 20-100 Å and can be patterned by ion sputtering.

4. The method for aligning semiconducting nanowires on a metal electrode as set forth in claim 1, wherein the zinc oxide nanowire is synthesized by the carbothermal reduction method using zinc oxide and graphite powder (99.9%; ˜325 mesh; 1:1 mixture) as a source material at 800-1000° C. for 1-120 minutes, while injecting argon (10-200 sccm) as a carrier gas and oxygen (0.1-10 sccm) as a reaction gas.

5. The method for aligning semiconducting nanowires on a metal electrode as set forth in claim 1, wherein the silicon nanowire is synthesized by the chemical vapor deposition under the reaction pressure of 1-100 Torr, while injecting a silane (SiH₄) gas and a hydrogen (H₂) gas diluted to 5% are injected to a metal-organic gas helium (He) at a flow rate of about 10-100 sccm and 10-200 sccm, respectively.

6. The method for aligning semiconducting nanowires on a metal electrode as set forth in claim 1, wherein the zinc oxide nanowire grows on gold (Au) when the reaction gas has an oxygen/argon ratio of 0.5-12 and the reaction temperature is about 800-850° C.

7. The method for aligning semiconducting nanowires on a metal electrode as set forth in claim 1, wherein the zinc oxide nanowire grows on platinum (Pt) and gold (Au) when the reaction gas has an oxygen/argon ratio of 1-10 and the reaction temperature is about 850-950° C.

8. The method for aligning semiconducting nanowires on a metal electrode as set forth in claim 1, wherein the zinc oxide nanowire grows on platinum (Pt) when the reaction gas has an oxygen/argon ratio of 2-12 and the reaction temperature is about 950-1000° C.

9. The method for aligning semiconducting nanowires on a metal electrode as set forth in claim 1, wherein the silicon nanowire grows on gold (Au) when the reaction gas has a silane (SiH₄)/hydrogen (H₂) ratio of 10-80 and the reaction temperature is about 500-600° C.

10. The method for aligning semiconducting nanowires on a metal electrode as set forth in claim 1, wherein the silicon nanowire grows on aluminum (Al) when the reaction gas has a silane (SiH₄)/hydrogen (H₂) ratio of 70-120 and the reaction temperature is about 550-700° C.

11. The method for aligning semiconducting nanowires on a metal electrode as set forth in claim 1, wherein the silicon nanowire grows on platinum (Pt) and gold (Au) when the reaction gas has a silane (SiH₄)/hydrogen (H₂) ratio of 10-100 and the reaction temperature is about 600-750° C.

12. The method for aligning semiconducting nanowires on a metal electrode as set forth in claim 1, wherein the silicon nanowire grows on platinum (Pt) when the reaction gas has a silane (SiH₄)/hydrogen (H₂) ratio of 20-120 and the reaction temperature is about 750-950° C.
